(19) United States
(12) Patent Application Publication
(10) Pub. No.: US 2026/0114094 A1
(43) Pub. Date: Apr. 23, 2026

(54) DISPLAY DEVICE

(71) Applicant: AUO Corporation, Hsinchu City (TW)

(72) Inventors: Yueh-Chi WU, Hsinchu City (TW); Chia-Jung WU, Hsinchu City (TW); Ti-Kuei YU, Hsinchu City (TW); Ya-Ling HSU, Hsinchu City (TW)

(21) Appl. No.: 18/922,458

(22) Filed: Oct. 22, 2024

(30) Foreign Application Priority Data
Feb. 1, 2024 (TW) 113104040

(51) Int. Cl. H01L 33/62; G02F 1/1362; H01L 25/075

(52) U.S. Cl. CPC H10H 20/857; G02F 1/136286; H10W 90/00

(57) ABSTRACT

A display device includes a primary display area, a signal source, a secondary display area, and a wire layer above the primary display area. The primary display area has a first side, a second side, and a third side. The signal source is at the first side. The secondary display area has a first light-emitting element adjacent to the second side and a second light-emitting element adjacent to the third side. The wire layer includes a first metal wire, a second metal wire, and a dummy metal wire. The first metal wire is connected to the signal source and the first light-emitting element. The second metal wire is electrically disconnected from the first metal wire. The second metal wire is connected to the signal source and the second light-emitting element. The dummy metal wire, the first metal wire, and the second metal wire form rhombus grids.

This application claims priority to Taiwan Application Serial Number 113104040, filed February 01, 2024, which is herein incorporated by reference.

### BACKGROUND

### Technical Field

The present disclosure relates to a display device. More particularly, the present disclosure relates to a tiling display device.

### Description of Related Art

To create a display device with a larger display area, small-sized conventional display modules are tiled together. This type of tiling display device is versatile and may be employed in numerous applications. Despite the benefits of tiling display devices, there are some challenges associated with this approach. For example, seams between adjacent or overlapping display modules may be present, and Moiré patterns may occur, which can adversely affect the viewing experience.

Accordingly, how to provide a display device to solve the aforementioned problems becomes an important issue to be solved by those in the industry.

### SUMMARY

An aspect of the disclosure is to provide a display device that may efficiently solve the aforementioned problems.

According to an embodiment of the disclosure, a display device includes a primary display area, a signal source, a secondary display area, and a wire layer. The primary display area has a first side, a second side, and a third side. The third side is opposite to the first side. The second side connects the first side and the third side. The signal source is disposed at the first side of the primary display area. The secondary display area extends from the second side to the third side of the primary display area. The secondary display area has a first light-emitting element and a second light-emitting element. The first light-emitting element is adjacent to the second side of the primary display area. The second light-emitting element is adjacent to the third side of the primary display area. The wire layer is above the primary display area and includes a first metal wire, a second metal wire, and a dummy metal wire. The first metal wire has a first end and a second end opposite to the first end. The first end is connected to the signal source. The second end is connected to the first light-emitting element. The second metal wire is electrically disconnected from the first metal wire. The second metal wire has a third end and a fourth end opposite to the third end. The third end is connected to the signal source. The fourth end is connected to the second light-emitting element. The dummy metal wire, the first metal wire, and the second metal wire form a plurality of rhombus grids.

In an embodiment of the disclosure, the primary display area includes a plurality of sub-pixel units. A length of one of the rhombus grids along a first direction is substantially twice a length of one of the sub-pixel units along the first direction. A width of the one of the rhombus grids along a second direction is substantially four times a width of the one of the sub-pixel units along the second direction. The second direction is substantially perpendicular to the first direction.

In an embodiment of the disclosure, the primary display area includes a plurality of sub-pixel units. A length of one of the rhombus grids along a first direction is substantially equal to a length of one of the sub-pixel units along the first direction. A width of the one of the rhombus grids along a second direction is substantially twice a width of the one of the sub-pixel units along the second direction. The second direction is substantially perpendicular to the first direction.

In an embodiment of the disclosure, the first metal wire and the second metal wire include different materials.

In an embodiment of the disclosure, the dummy metal wire and the first metal wire are disposed on a same plane. The dummy metal wire and the first metal wire include a same material.

In an embodiment of the disclosure, the dummy metal wire and the second metal wire are disposed on a same plane. The dummy metal wire and the second metal wire include a same material.

In an embodiment of the disclosure, the dummy metal wire is electrically connected to a ground potential.

In an embodiment of the disclosure, the display device further includes a ground potential line. The ground potential line extends from the second side to the third side of the primary display area. The dummy metal wire extends and connects to the ground potential line. The first light-emitting element has a first electrode and a second electrode. The first electrode is electrically connected to the first metal wire. The second electrode is electrically connected to the ground potential line.

In an embodiment of the disclosure, the second light-emitting element has a third electrode and a fourth electrode. The third electrode is electrically connected to the second metal wire. The fourth electrode is electrically connected to the ground potential line.

In an embodiment of the disclosure, the secondary display area further includes a third light-emitting element. The third light-emitting element is adjacent to the second side of the primary display area. The third light-emitting element has a fifth electrode and a sixth electrode. The fifth electrode is electrically connected to the first metal wire. The sixth electrode is in an open-circuit state.

According to another embodiment of the disclosure, a display device includes a primary display area and a wire layer. The primary display area has a first side, a second side, and a third side. The third side is opposite to the first side. The second side connects the first side and the third side. The wire layer is above the primary display area and includes a first metal wire, a second metal wire, and a dummy metal wire. The first metal wire has a first portion and a second portion. A centerline of the first portion extends from the first side of the primary display area substantially along a first direction. A centerline of the second portion extends substantially along a second direction through the second side of the primary display area. The second direction and the first direction intersect. The second metal wire is electrically disconnected from the first metal wire. A centerline of the second metal wire extends from the first side of the primary display area substantially along the first direction through the third side of the primary display area. The dummy metal wire is electrically connected to a ground potential. The dummy metal wire, the first metal wire, and the second metal wire form a plurality of rhombus grids.

In an embodiment of the disclosure, the display device further includes a signal source and a secondary display area. The signal source is disposed at the first side of the primary display area. The secondary display area has a first light-emitting element and a second light-emitting element. The first light-emitting element is adjacent to the second side of the primary display area. The second light-emitting element is adjacent to the third side of the primary display area. The first portion of the first metal wire is connected to the signal source. The second portion of the first metal wire is connected to the first light-emitting element. Two ends of the second metal wire are connected to the signal source and the second light-emitting element, respectively.

In an embodiment of the disclosure, the display device further includes a ground potential line. The ground potential line extends from the second side to the third side of the primary display area. The dummy metal wire extends and connects to the ground potential line. The first light-emitting element has a first electrode and a second electrode. The first electrode is electrically connected to the first metal wire. The second electrode is electrically connected to the ground potential line.

In an embodiment of the disclosure, the second light-emitting element has a third electrode and a fourth electrode. The third electrode is electrically connected to the second metal wire. The fourth electrode is electrically connected to the ground potential line.

In an embodiment of the disclosure, the secondary display area further includes a third light-emitting element. The third light-emitting element is adjacent to the second side of the primary display area. The third light-emitting element has a fifth electrode and a sixth electrode. The fifth electrode is electrically connected to the first metal wire. The sixth electrode is in an open-circuit state.

In an embodiment of the disclosure, the second direction is substantially perpendicular to the first direction.

In an embodiment of the disclosure, the primary display area includes a plurality of sub-pixel units. A length of one of the rhombus grids along the first direction is substantially twice a length of one of the sub-pixel units along the first direction. A width of the one of the rhombus grids along the second direction is substantially four times a width of the one of the sub-pixel units along the second direction.

In an embodiment of the disclosure, the primary display area includes a plurality of sub-pixel units. A length of one of the rhombus grids along the first direction is substantially equal to a length of one of the sub-pixel units along the first direction. A width of the one of the rhombus grids along the second direction is substantially twice a width of the one of the sub-pixel units along the second direction.

In an embodiment of the disclosure, the dummy metal wire and the first metal wire are disposed on a same plane. The dummy metal wire and the first metal wire include a same material.

In an embodiment of the disclosure, the dummy metal wire and the second metal wire are disposed on a same plane. The dummy metal wire and the second metal wire include a same material.

Accordingly, in the display device of some embodiments of the present disclosure, by disposing the secondary display area with the light-emitting elements around the periphery of the primary display area, visible lines at the adjacency of the primary display area with another primary display area may be avoided after tiling. In addition, the wire layer for the light-emitting elements in the secondary display area is above the primary display area. By arranging the metal wires of the wire layer and the sub-pixel units of the primary display area in such a way that a non-zero included angle exists between an edge of each of the rhombus grids formed by the metal wires and an edge of each of the rectangular patterns of the sub-pixel units, mutual interference between the two patterns may be prevented, thereby reducing Moiré pattern generation. In greater detail, the signal source is disposed at one side of the primary display area, and the secondary display area is disposed around the periphery of other sides of the primary display area. To drive the light-emitting elements, the metal wires of the wire layer extend from the signal source over the primary display area to the light-emitting elements in the secondary display area. Moreover, the wire layer further includes the dummy metal wires, so that the metal wires in the wire layer jointly form rhombus grids. Accordingly, a seamless tiling display device may be achieved with reduced/eliminated Moiré effect, thereby enhancing the viewing experience.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a top view of a display device according to some embodiments of the present disclosure;

FIG. 2 is a partial enlarged view of a display device according to some embodiments of the present disclosure;

FIG. 3 and FIG. 4 are partial cross-sectional views of a display device according to some embodiments of the present disclosure;

FIG. 5 and FIG. 6 are partial enlarged views of a display device according to some other embodiments of the present disclosure;

FIG. 7 is a partial enlarged view of a display device according to some other embodiments of the present disclosure;

FIG. 8 and FIG. 9 are partial cross-sectional views of a display device according to some other embodiments of the present disclosure;

FIG. 10 is a partial enlarged view of a display device according to some other embodiments of the present disclosure; and

FIG. 11 is a schematic diagram of a secondary display area of a display device according to some other embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

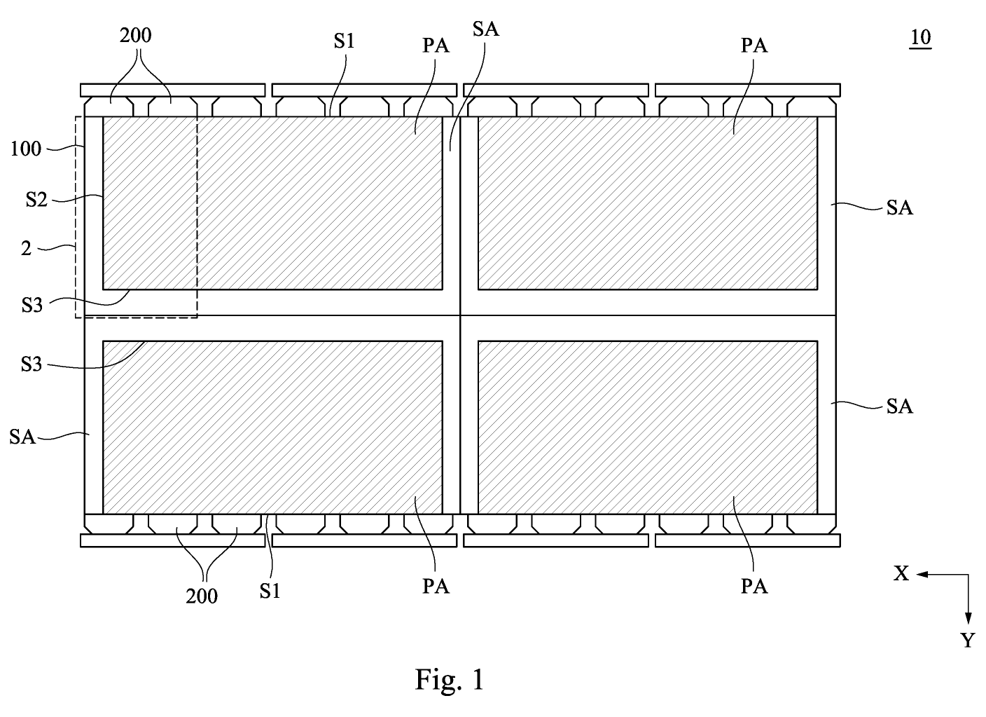

Reference is made to FIG. 1. FIG. 1 is a top view of a display device 10 according to some embodiments of the present disclosure. The display device 10 includes a primary display area PA. The primary display area PA has a first side S1, a second side S2, and a third side S3. The third side S3 is opposite to the first side S1. The second side S2 connects the first side S1 and the third side S3.

In some embodiments, the primary display area PA includes a liquid crystal (LC) display module, an organic light-emitting diode (OLED) display module, a micro light-emitting diode (micro LED) display module, or the like. A sealant structure is usually disposed around the primary display area PA. However, when display modules are tiled (for example, four display modules are tiled together in FIG. 1), visible lines or gaps may appear at the borders of the display modules if the sealant structure does not include any display elements. This may be particularly noticeable when displaying continuous images or videos across multiple display modules, thus adversely affecting the viewing experience.

Therefore, in some embodiments of the present disclosure, the display device 10 includes a secondary display area SA. The secondary display area SA extends from the second side S2 to the third side S3 of the primary display area PA. The secondary display area SA includes a plurality of light-emitting elements. As shown in FIG. 1, the secondary display area SA is disposed at the periphery of the primary display area PA with the light-emitting elements. During the tiling process, the secondary display areas SA at the periphery of several primary display areas PA are connected to one another. Through the light-emitting elements included in these secondary display areas SA, visible lines may be avoided. In some embodiments, the light-emitting elements may be micro light-emitting diodes or mini light-emitting diodes (mini LED).

As shown in FIG. 1, the display device 10 further includes a wire layer 100 and a signal source 200. The wire layer 100 is above the primary display area PA. The signal source 200 is at the first side S1 of the primary display area PA. The wire layer 100 is electrically connected to the signal source 200 and the light-emitting elements in the secondary display area SA. The wire layer 100 is configured to receive driving signals from the signal source 200 and transmit the driving signals to the light-emitting elements. In some embodiments, the signal source 200 includes a flexible printed circuit (FPC) or a chip on film (COF).

Since the wire layer 100 is above the primary display area PA, Moiré patterns may be produced due to the superposition of the grid pattern formed by the wirings of the wire layer 100 and the grid pattern of sub-pixel units of the primary display area PA, resulting in image degradation. Therefore, in some embodiments of the present disclosure, the grid pattern of the primary display area PA is in the form of rectangular grids, and the wire layer 100 is in the form of rhombus grids. As such, they are arranged in a certain way to prevent the grid patterns of the two from interfering with each other, thereby reducing the Moiré effect. The structure of the wire layer 100 will be described in detail in the following paragraphs.

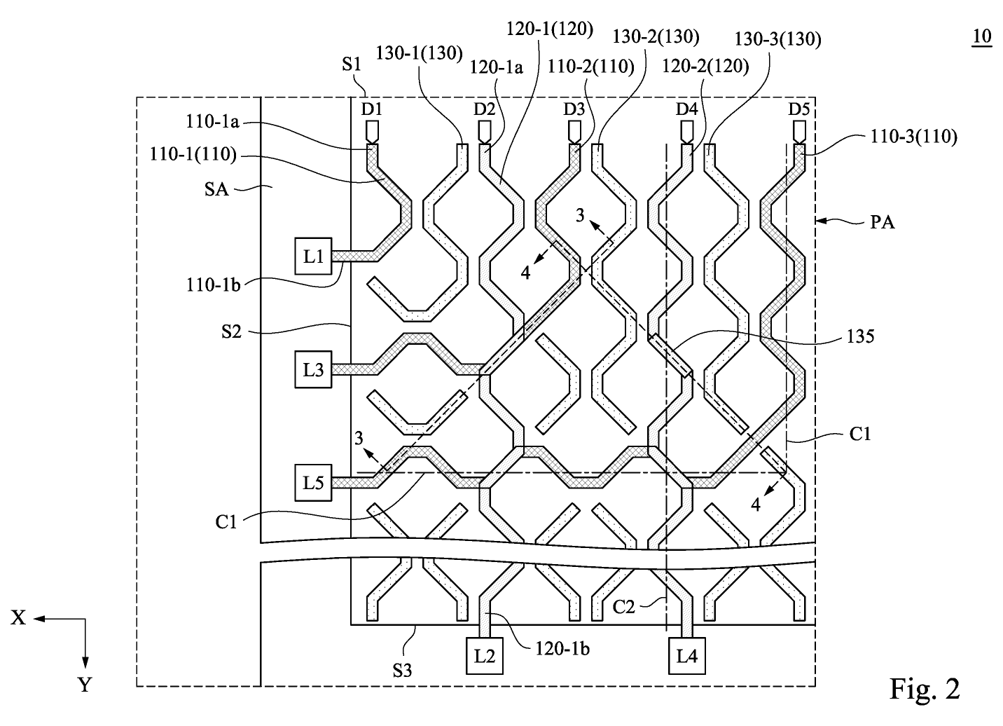

Reference is made to FIG. 2. FIG. 2 is a partial enlarged view of a square 2 of the display device 10 in FIG. 1 according to some embodiments of the present disclosure. As aforementioned, the secondary display area SA includes a plurality of light-emitting elements, such as the first light-emitting element L1, the first light-emitting element L3, and the first light-emitting element L5 adjacent to the second side S2 of the primary display area PA as well as the second light-emitting element L2 and the second light-emitting element L4 adjacent to the third side S3 of the primary display area PA. As shown in FIG. 2, the wire layer 100 includes first metal wires 110, second metal wires 120, and dummy metal wires 130. The first metal wires 110, the second metal wires 120, and the dummy metal wires 130 form a plurality of rhombus grids.

Each of the first metal wires 110 has a first end and a second end opposite to the first end. The first end is connected to the signal source, and the second end is connected to one of the first light-emitting elements. For example, the first end 110-1a of the first metal wire 110-1 is connected to the signal source, and the second end 110-1b is connected to the first light-emitting element L1 to receive and transmit the signal D1 to the first light-emitting element L1. Similarly, the first metal wire 110-2 receives and transmits the signal D3 to the first light-emitting element L3. The first metal wire 110-3 receives and transmits the signal D5 to the first light-emitting element L5.

To be more specific, as shown in FIG. 2, the first metal wires 110 extend from the first side S1 of the primary display area PA substantially along a first direction (e.g., the direction Y) above the primary display area PA, and then divert to extend substantially along a second direction (e.g., the direction X) through the second side S2 of the primary display area PA to the first light-emitting elements. It should be noted that the first metal wires 110 can be zig-zag lines, and the term "extending substantially along a direction" means that centerlines of the zig-zag lines extend along the aforementioned direction. For example, as shown in FIG. 2, a centerline C1 of the first metal wire 110-3 extends from the first side S1 in a direction parallel to the direction Y, then diverts 90 degrees and extends in another direction parallel to the direction X through the second side S2 to the first light-emitting element L5.

The second metal wires 120 are electrically disconnected from the first metal wires 110. Each of the second metal wires 120 has a third end and a fourth end opposite to the third end. The third end is connected to the signal source. The fourth end is connected to one of the second light-emitting elements. For example, the second metal wire 120-1 has a third end 120-1a and a fourth end 120-1b opposite to the third end 120-1a. The third end 120-1a is connected to the signal source, and the fourth end 120-1b is connected to the second light-emitting element L2 to receive and transmit the signal D2 to the second light-emitting element L2. Similarly, the second metal wire 120-2 receives and transmits the signal D4 to the second light-emitting element L4.

In greater detail, as shown in FIG. 2, the second metal wires 120 extend from the first side S1 of the primary display area PA substantially along the first direction (e.g., the direction Y) above the primary display area PA and through the third side S3 of the primary display area PA to the second light-emitting element. Similarly, the second metal wires 120 may be zig-zag lines. For example, as shown in FIG. 2, a centerline C2 of the second metal wire 120-2 extends from the first side S1 in a direction parallel to the direction Y through the third side S3 to the second light-emitting element L4.

As shown in FIG. 2, in a top view, the dummy metal wires 130, such as the dummy metal wire 130-1, the dummy metal wire 130-2, and the dummy metal wire 130-3, are disposed among the first metal wires 110 and the second metal wires 120 with irregular lengths and extending directions. The dummy metal wires 130 are zig-zag lines extending in various directions such that the dummy metal wires 130 form the rhombus grids with the first metal wires 110 and the second metal wires 120. In some embodiments, the dummy metal wires 130 are completely disposed above the primary display area PA.

In some embodiments, since the first metal wires 110 and the second metal wires 120 partially overlap, the appearance at the overlapping parts of the device may be different from the appearance of other parts of the device. For example, there are overlapping parts between the first metal wire 110-2 and the second metal wire 120-1, between the first metal wire 110-3 and the second metal wire 120-1, as well as between the first metal wire 110-3 and the second metal wire 120-2. For the sake of appearance, the display device 10 further includes a dummy metal wire 135 disposed at a counterpart position of one of the aforementioned overlapping parts. To be more specific, the dummy metal wire 135 is disposed overlapping a part of the second metal wire 120-2. The position of the dummy metal wire 135 is then deliberately selected so that the overlapping part between the second metal wire 120-2 and the dummy metal wire 135 is mirror-symmetrical to the overlapping part between the second metal wire 120-1 and the first metal wire 110-2 with respect to the direction Y. In addition, the overlapping part between the second metal wire 120-1 and the first metal wire 110-3 is mirror-symmetrical to the overlapping part between the second metal wire 120-2 and the first metal wire 110-3 with respect to the direction Y. As such, in a cross-sectional view, the height is more even, and the transmittance is more symmetrical over the primary display area when viewed from above.

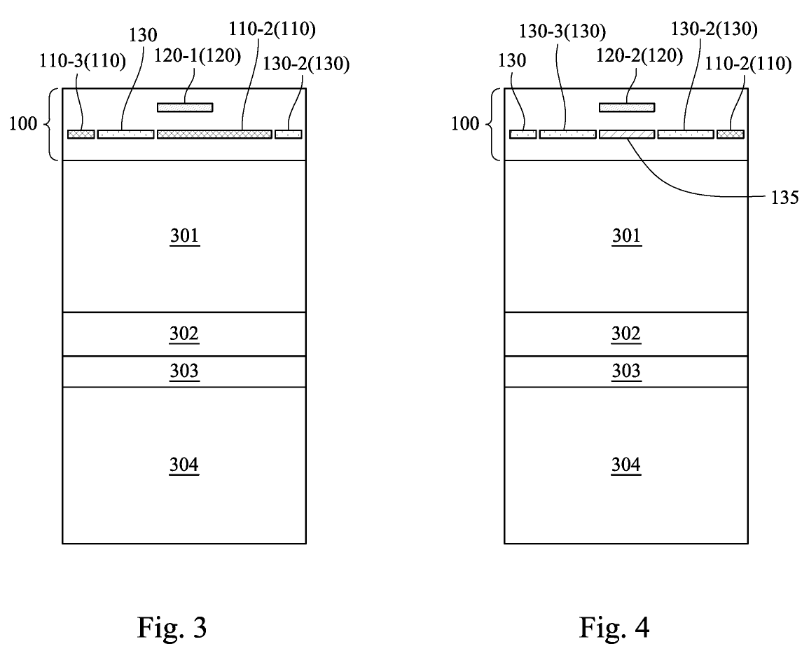

Reference is made to FIG. 3. FIG. 3 is a partial cross-sectional view of the display device 10 along a line 3-3 in FIG. 2 according to some embodiments of the present disclosure. In some embodiments, the display device 10 further includes an upper substrate 301, a liquid crystal layer 302, a liquid crystal wire layer 303, and a lower substrate 304. In some embodiments, the wire layer 100 is on the upper substrate 301.

As shown in FIG. 3, in some embodiments, the first metal wires 110 and the dummy metal wires 130 are on a same plane. In some embodiments, the first metal wires 110 and the dummy metal wires 130 include a same metal material, such as copper (Cu) or aluminum (Al). In this way, the first metal wires 110 and the dummy metal wires 130 may be formed in one single process, thereby saving process time and cost. In addition, the first metal wires 110 and the dummy metal wires 130 have a same reflectivity, which can minimize the difference in appearance.

Reference is made to FIG. 4. FIG. 4 is a partial cross-sectional view of the display device 10 along a line 4-4 in FIG. 2 according to some embodiments of the present disclosure. As shown in FIG. 4, the first metal wires 110, the dummy metal wires 130 and the dummy metal wire 135 are on a same plane. As aforementioned, the dummy metal wire 135 overlaps the second metal wire 120-2 and its position is a counterpart of the overlapping part of the first metal wire 110-2 and the second metal wire 120-1 in FIG. 3. Similarly, the dummy metal wire 135 may include a same metal material as the first metal wires 110 and the dummy metal wires 130.

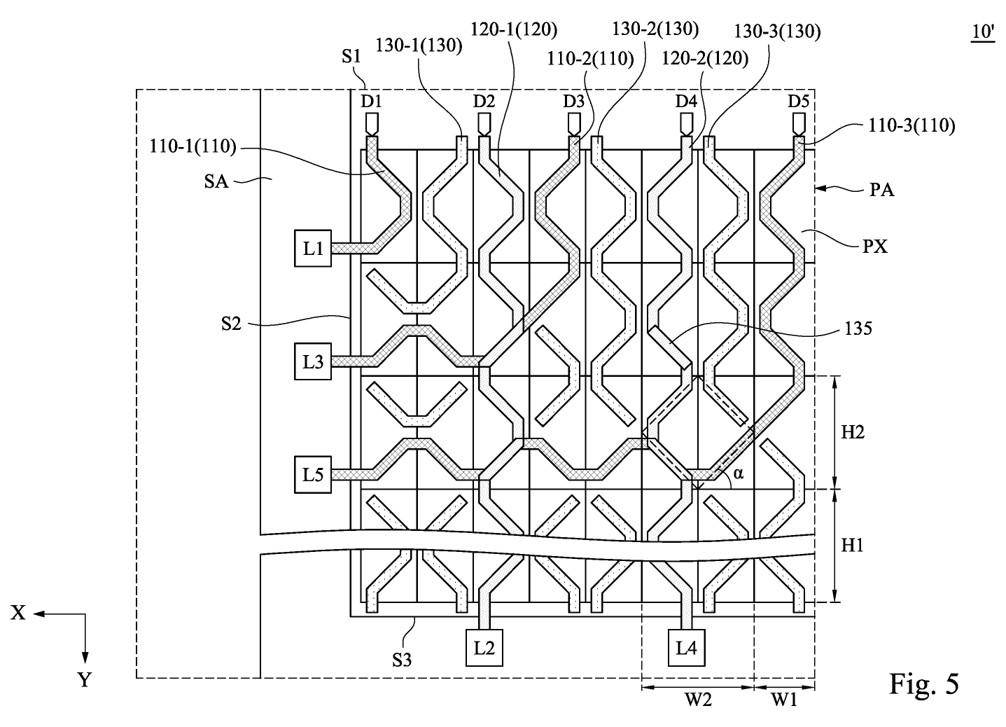

Reference is made to FIG. 5. FIG. 5 is a partial enlarged view of a display device 10′ according to some other embodiments of the present disclosure. As shown in FIG. 5, the primary display area PA further includes a plurality of sub-pixel units PX arranged in an array along the direction X and the direction Y. Each of the sub-pixel units PX has a width W1 along the direction X and a length H1 along the direction Y. Each of the rhombus grids formed by the first metal wires 110, the second metal wires 120 and the dummy metal wires 130 has a width W2 along the direction X and a length H2 along the direction Y. In some embodiments, the width W2 is substantially twice the width W1, and the length H2 is substantially equal to the length H1. In addition, as shown in FIG. 5, there is a non-zero included angle α between an edge of each of the rhombus grids and an edge of each of the sub-pixel units PX. Such wiring structure is suitable for portrait display devices (i.e., characteristic lengths in the direction X are smaller than characteristic lengths in the direction Y) and can provide high pixel density in the secondary display area SA, but this disclosure is not limited thereto.

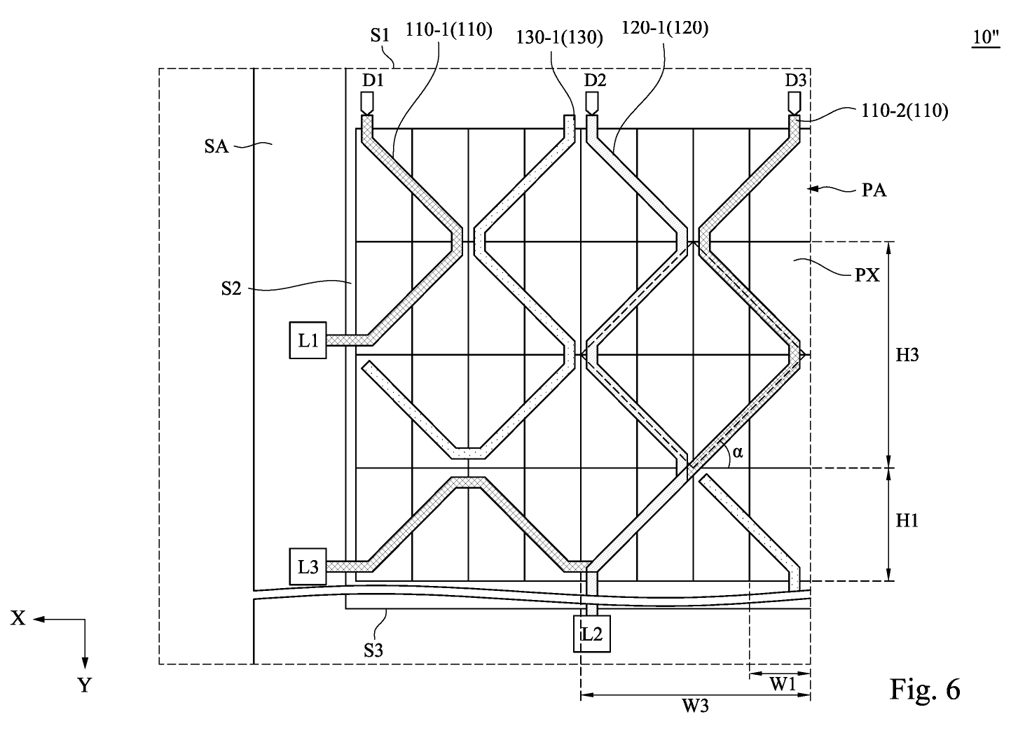

Reference is made to FIG. 6. FIG. 6 is a partial enlarged view of the display device 10" according to some other embodiments of the present disclosure. The difference between the display device 10" and the display device 10' is that the first metal wires 110, the second metal wires 120, and the dummy metal wires 130 are more sparsely distributed, so that a width W3 and a length H3 of each of the rhombus grids formed are substantially twice the width W2 and substantially twice the length H2, respectively. In other words, the width W3 is substantially four times the width W1, and the length H3 is substantially twice the length H1, as shown in FIG. 6. Similarly, there is a non-zero angle α between an edge of each of rhombus grids and an edge of each of the sub-pixel units PX. The sparser the distribution of metal wires in the wire layer 100, the less the aperture ratio loss of the display area, and the better the effect of reducing Moiré patterns. Such wiring structure is suitable for landscape display devices (i.e., characteristic lengths in the direction X is greater than characteristic lengths in the direction Y), but the present disclosure is not limited thereto.

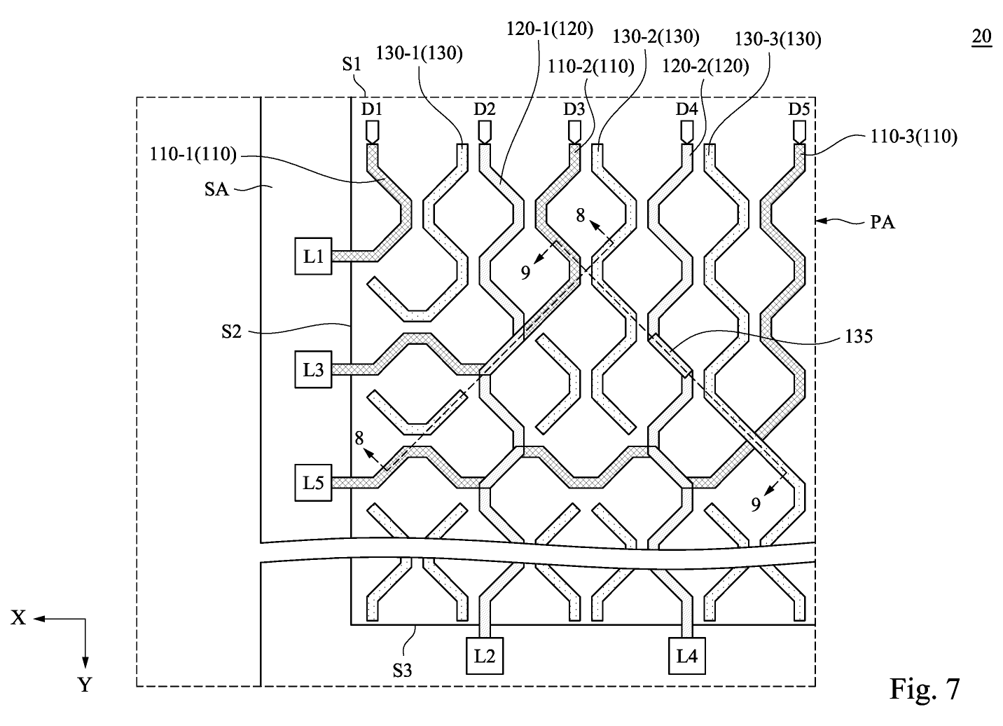

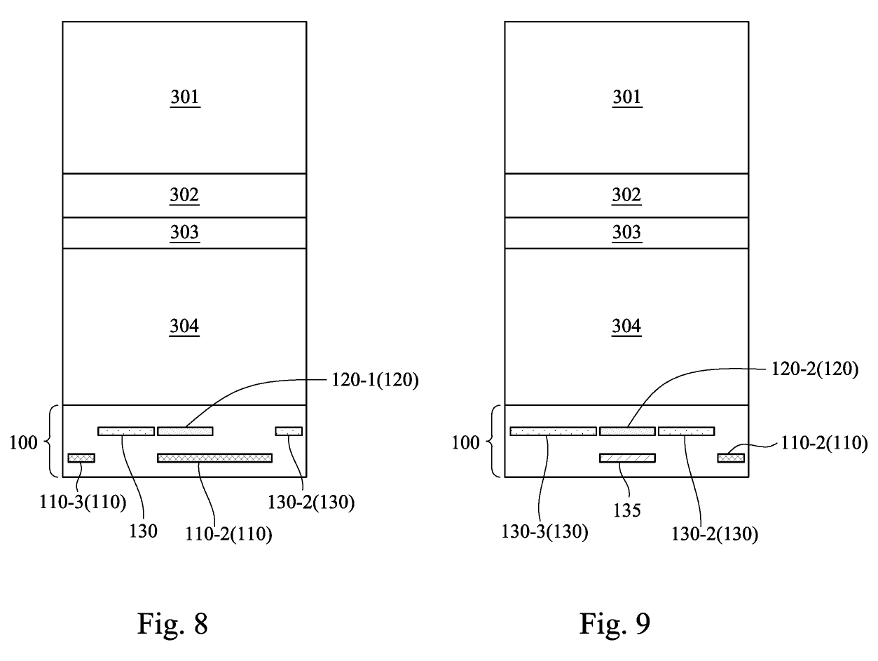

Reference is made to FIG. 7 to FIG. 9. FIG. 7 is a partial enlarged view of a display device 20 according to some other embodiments of the present disclosure. FIG. 8 is a partial cross-sectional view of the display device 20 along a line 8-8 in FIG. 7. FIG. 9 is a partial cross-sectional view of the display device 20 along a line 9-9 in FIG. 7. One of the differences between the display device 20 and the display device 10 is that the dummy metal wires 130 and the second metal wires 120 of the display device 20 are disposed on a same plane. Therefore, as shown in FIG. 7, the dummy metal wire 130-3 may extend over the first metal wire 110-3. In addition, the dummy metal wires 130 and the second metal wires 120 may include a same metal material, such as copper or aluminum. Therefore, the second metal wires 120 and the dummy metal wires 130 may be formed in one single process, and the second metal wires 120 and dummy metal wires 130 may have a same reflectivity.

Reference is made to FIG. 8 and FIG. 9. As aforementioned, the dummy metal wires 130 and the second metal wires 120 of the display device 20 are disposed on the same plane. In addition, another difference between the display device 20 and the display device 10 is that the wire layer 100 of the display device 20 is below the lower substrate 304, as shown in FIG. 8 and FIG. 9.

It should be noted that the dummy metal wire 135 of the display device 20 is disposed on the same plane as the first metal wires 110, overlapping the second metal wire 120-2, and disposed at a position being a counterpart of the overlapping part between the first metal wire 110-2 and the second metal wire 120-1 shown in FIG. 8.

In some embodiments, the first metal wires 110 and the second metal wires 120 may include different metal materials. In such embodiments, the dummy metal wires 130 and the dummy metal wire 135 may include different metal materials.

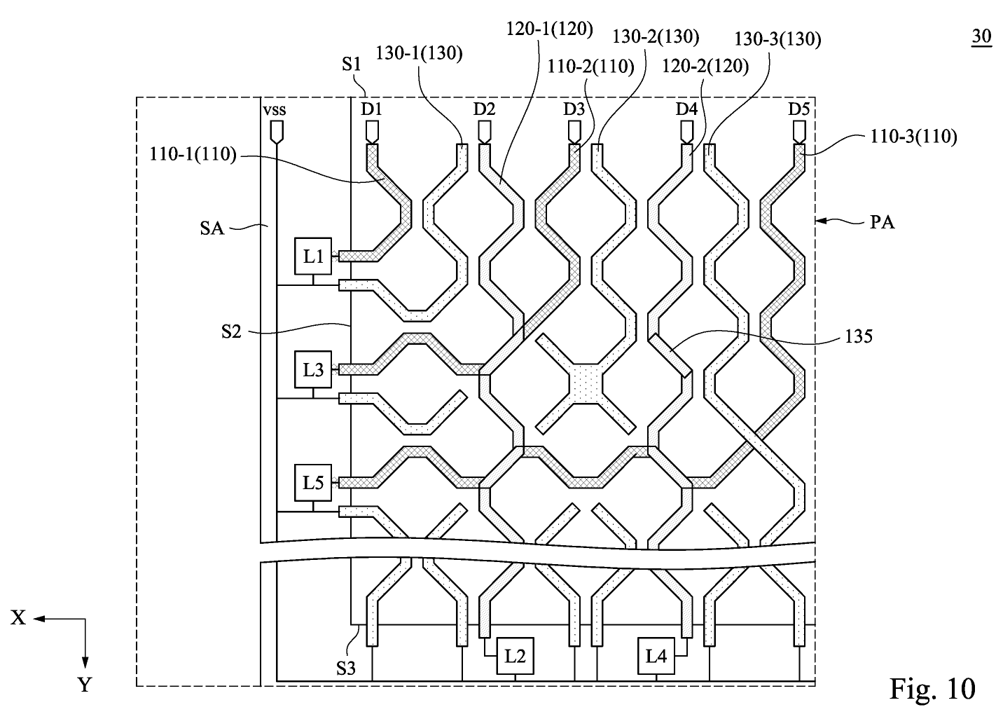

Reference is made to FIG. 10. FIG. 10 is a partial enlarged view of a display device 30 according to some other embodiments of the present disclosure. One of the differences between the display device 30 and the display device 10 is that the display device 30 further includes a ground potential line VSS. In some embodiments, one end of each of the dummy metal wires 130 extends into the secondary display area SA and is electrically connected to the ground potential line VSS, as shown in FIG. 10. In other words, the dummy metal wires 130 and the ground potential line VSS form a mesh structure over the primary display area PA and the secondary display area SA and are configured to be electrically connected to a ground potential.

In greater detail, each of the first light-emitting elements has a first electrode and a second electrode. The first electrode is electrically connected to one of the first metal wires 110. The second electrode is electrically connected to the ground potential line VSS. Similarly, each of the second light-emitting elements has a third electrode and a fourth electrode. The third electrode is electrically connected to one of the second metal wires 120. The fourth electrode is electrically connected to the ground potential line VSS.

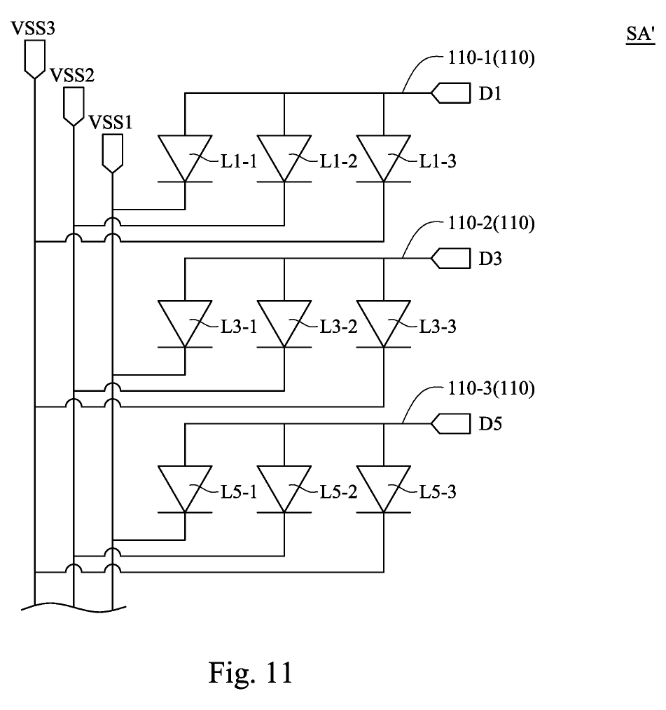

Reference is made to FIG. 11. FIG. 11 is a schematic diagram of a secondary display area SA' of a display device according to some other embodiments of the present disclosure. One of the differences between the secondary display area SA' and the secondary display area SA of the display device 10 is that the first electrodes of the first light-emitting elements in the secondary display area SA' are connected to a same one of the first metal wires 110, while the second electrodes of the first light-emitting elements are connected to different ground potential lines. For example, the first electrodes of the first light-emitting element L1-1, the first light-emitting element L1-2, and the first light-emitting element L1-3 are connected to the first metal wire 110-1 to receive a same driving signal D1. At the same time, the second electrodes of the first light-emitting element L1-1, the first light-emitting element L1-2, and the first light-emitting element L1-3 are connected to a ground potential line VSS1, a ground potential line VSS2, and a ground potential line VSS3, respectively, as shown in FIG. 11. Similarly, the first electrodes of the first light-emitting element L3-1, the first light-emitting element L3-2, and the first light-emitting element L3-3 are connected to the first metal wire 110-2 to receive a same driving signal D3. The second electrodes of the first light-emitting element L3-1, the first light-emitting element L3-2, and the first light-emitting element L3-3 are connected to the ground potential line VSS1, the ground potential line VSS2, and the ground potential line VSS3, respectively. The first electrodes of the first light-emitting element L5-1, the first light-emitting element L5-2, and the first light-emitting element L5-3 are connected to the first metal wire 110-3 to receive a same driving signal D5. The second electrodes of the first light-emitting element L5-1, the first light-emitting element L5-2, and the first light-emitting element L5-3 are connected to the ground potential line VSS1, the ground potential line VSS2, and the ground potential line VSS3, respectively.

As such, the number of the light-emitting elements disposed in the secondary display area SA' may be increased without altering the number of pins of the signal source and the number of metal wires in the wire layer 100. Additionally, the second electrodes of different first light-emitting elements may be individually set to either a closed-circuit state or open-circuit state, thereby controlling the display effect of each of the first light-emitting elements.

For example, the first light-emitting element L1-1 is configured to emit a red light, the first light-emitting element L1-2 is configured to emit a green light, and the first light-emitting element L1-3 is configured to emit a blue light. When the second electrode of the first light-emitting element L1-1 is electrically connected to the ground potential line VSS1 and the second electrodes of the first light-emitting element L1-2 and the first light-emitting element L1-3 are electrically disconnected from the ground potential line VSS2 and the ground potential line VSS3, respectively, the red light may be solely displayed. A similar configuration applies to the second light-emitting elements as well.

In some embodiments, more than three light-emitting elements may receive the same driving signal and be connected to different ground potential lines, respectively. For example, nine, twelve, or fifteen light-emitting elements may apply. Correspondingly, the display device includes more ground potential lines disposed at the periphery of the primary display area PA.

According to the foregoing recitations of the embodiments of the disclosure, it may be seen that in the display device of some embodiments of the present disclosure, by disposing the secondary display area with the light-emitting elements around the periphery of the primary display area, visible lines at the adjacency of the primary display area with another primary display area may be avoided after tiling. In addition, the wire layer for the light-emitting elements in the secondary display area is above the primary display area. By arranging the metal wires of the wire layer and the sub-pixel units of the primary display area in such a way that a non-zero included angle exists between an edge of each of the rhombus grids formed by the metal wires and an edge of each of the rectangular patterns of the sub-pixel units, mutual interference between the two patterns may be prevented, thereby reducing Moiré pattern generation. In greater detail, the signal source is disposed at one side of the primary display area, and the secondary display area is disposed around the periphery of other sides of the primary display area. To drive the light-emitting elements, the metal wires of the wire layer extend from the signal source over the primary display area to the light-emitting elements in the secondary display area. Moreover, the wire layer further includes the dummy metal wires, so that the metal wires in the wire layer jointly form rhombus grids. Accordingly, a seamless tiling display device may be achieved with reduced/eliminated Moiré effect, thereby enhancing the viewing experience.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A display device, comprising:
a primary display area having a first side, a second side, and a third side, wherein the third side is opposite to the first side, and the second side connects the first side and the third side;
a signal source disposed at the first side of the primary display area;
a secondary display area extending from the second side to the third side of the primary display area, wherein the secondary display area has a first light-emitting element adjacent to the second side of the primary display area, and a second light-emitting element adjacent to the third side of the primary display area; and
a wire layer above the primary display area and comprising :
a first metal wire having a first end and a second end opposite to the first end, wherein the first end is connected to the signal source, and the second end is connected to the first light-emitting element;
a second metal wire electrically disconnected from the first metal wire and having a third end and a fourth end opposite to the third end, wherein the third end is connected to the signal source, and the fourth end is connected to the second light-emitting element; and
a dummy metal wire, wherein the dummy metal wire, the first metal wire, and the second metal wire form a plurality of rhombus grids.

2. The display device of claim 1, wherein the primary display area comprises a plurality of sub-pixel units, wherein a length of one of the rhombus grids along a first direction is substantially twice a length of one of the sub-pixel units along the first direction, a width of the one of the rhombus grids along a second direction is substantially four times a width of the one of the sub-pixel units along the second direction, and the second direction is substantially perpendicular to the first direction.

3. The display device of claim 1, wherein the primary display area comprises a plurality of sub-pixel units, wherein a length of one of the rhombus grids along a first direction is substantially equal to a length of one of the sub-pixel units along the first direction, a width of the one of the rhombus grids along a second direction is substantially twice a width of the one of the sub-pixel units along the second direction, and the second direction is substantially perpendicular to the first direction.

4. The display device of claim 1, wherein the first metal wire and the second metal wire comprise different materials.

5. The display device of claim 1, wherein the dummy metal wire and the first metal wire are disposed on a same plane, and the dummy metal wire and the first metal wire comprise a same material.

6. The display device of claim 1, wherein the dummy metal wire and the second metal wire are disposed on a same plane, and the dummy metal wire and the second metal wire comprise a same material.

7. The display device of claim 6, wherein the dummy metal wire is electrically connected to a ground potential.

8. The display device of claim 7, further comprising a ground potential line extending from the second side to the third side of the primary display area, wherein the dummy metal wire extends and connects to the ground potential line, and the first light-emitting element has a first electrode and a second electrode, wherein the first electrode is electrically connected to the first metal wire, and the second electrode is electrically connected to the ground potential line.

9. The display device of claim 8, wherein the second light-emitting element has a third electrode and a fourth electrode, wherein the third electrode is electrically connected to the second metal wire, and the fourth electrode is electrically connected to the ground potential line.

10. The display device of claim 8, wherein the secondary display area further comprises a third light-emitting element adjacent to the second side of the primary display area, wherein the third light-emitting element has a fifth electrode and a sixth electrode, the fifth electrode is electrically connected to the first metal wire, and the sixth electrode is in an open-circuit state.

11. A display device, comprising:
a primary display area having a first side, a second side, and a third side, wherein the third side is opposite to the first side, and the second side connects the first side and the third side; and
a wire layer above the primary display area and comprising :
a first metal wire having a first portion and a second portion, wherein a centerline of the first portion extends from the first side of the primary display area substantially along a first direction, a centerline of the second portion extends substantially along a second direction through the second side of the primary display area, and the second direction and the first direction intersect;
a second metal wire electrically disconnected from the first metal wire, wherein a centerline of the second metal wire extends from the first side of the primary display area substantially along the first direction through the third side of the primary display area; and
a dummy metal wire electrically connected to a ground potential, wherein the dummy metal wire, the first metal wire, and the second metal wire form a plurality of rhombus grids.

12. The display device of claim 11, further comprising:
a signal source disposed at the first side of the primary display area; and
a secondary display area having a first light-emitting element adjacent to the second side of the primary display area and a second light-emitting element adjacent to the third side of the primary display area,
wherein the first portion of the first metal wire is connected to the signal source, the second portion of the first metal wire is connected to the first light-emitting element, and two ends of the second metal wire are connected to the signal source and the second light-emitting element, respectively.

13. The display device of claim 12, further comprising a ground potential line extending from the second side to the third side of the primary display area, wherein the dummy metal wire extends and connects to the ground potential line, and the first light-emitting element has a first electrode and a second electrode, wherein the first electrode is electrically connected to the first metal wire, and the second electrode is electrically connected to the ground potential line.

14. The display device of claim 13, wherein the second light-emitting element has a third electrode and a fourth electrode, wherein the third electrode is electrically connected to the second metal wire, and the fourth electrode is electrically connected to the ground potential line.

15. The display device of claim 13, wherein the secondary display area further comprises a third light-emitting element adjacent to the second side of the primary display area, wherein the third light-emitting element has a fifth electrode and a sixth electrode, the fifth electrode is electrically connected to the first metal wire, and the sixth electrode is in an open-circuit state.

16. The display device of claim 11, wherein the second direction is substantially perpendicular to the first direction.

17. The display device of claim 11, wherein the primary display area comprises a plurality of sub-pixel units, wherein a length of one of the rhombus grids along the first direction is substantially twice a length of one of the sub-pixel units along the first direction, and a width of the one of the rhombus grids along the second direction is substantially four times a width of the one of the sub-pixel units along the second direction.

18. The display device of claim 11, wherein the primary display area comprises a plurality of sub-pixel units, wherein a length of one of the rhombus grids along the first direction is substantially equal to a length of one of the sub-pixel units along the first direction, and a width of the one of the rhombus grids along the second direction is substantially twice a width of the one of the sub-pixel units along the second direction.

19. The display device of claim 11, wherein the dummy metal wire and the first metal wire are disposed on a same plane, and the dummy metal wire and the first metal wire comprise a same material.

20. The display device of claim 11, wherein the dummy metal wire and the second metal wire are disposed on a same plane, and the dummy metal wire and the second metal wire comprise a same material.
